(19) United States
(12) Patent Application Publication
(10) Pub. No.: US 2012/0147448 A1
(43) Pub. Date: Jun. 14, 2012

(54) ELECTROCHROMIC DEVICE

(75) Inventors: Zvi Yaniv, Austin, TX (US); Giuseppe Chidichimo, Rende (Cs) (IT); Bruna Clara De Simone, S. Fili (Cs) (IT); Daniela Imbardelli, Rende (Csw) (IT)

(73) Assignee: APPLIED NANOTECH HOLDINGS, INC,, Austin, TX (US)

(21) Appl. No.: 13/148,719

(22) PCT Filed: Feb. 10, 2010
(86) PCT No.: PCT/US10/23767

§ 371 Date: Feb. 28, 2012

Related U.S. Application Data
(60) Provisional application No. 61/151,423, filed on Feb. 10, 2009.
(60) Provisional application No. 61/233,371, filed on Aug. 12, 2009.

(51) Int. Cl. G02F 1/161; H05K 3/02

(52) U.S. Cl. 359/265; 29/846

(57) ABSTRACT

A method for manufacturing an electrochromic window positions a pattern of conductive lines over a first transparent substrate, a transparent conductive film over the pattern of conductive lines and first transparent substrate, and an electrochromic layer over the transparent conductive film, wherein the transparent conductive layer is a physical barrier separating the electrochromic layer from the pattern of conductive lines. The first transparent substrate may be flexible. The pattern of conductive lines and transparent conductive film may be deposited and processed at a temperature less than 180 degrees C. The pattern of conductive lines may be deposited on the first transparent substrate by printing techniques.

This application claims priority to U.S. Provisional Application Ser. Nos. 61/233,371 and 61/151,423, which are hereby incorporated by reference herein.

### BACKGROUND INFORMATION

In the flexible electronic industry, flexible displays, electrochromic windows, and solar cells, etc. need highly optically transmissive properties in the visible range as well as having a highly electrically conductive surface. For example, for the expensive active matrix LCD industry, high quality ITO films are deposited at relatively high temperatures by spattering or evaporation techniques in order to achieve high optical transmissivity and electrical resistivity not larger than 10 ohm/sq, and more preferably 1 ohm/sq (“ohm/sq” is a common unit for “ohms per square,” which is dimensionally equal to an ohm, but is used for sheet resistance). As these applications increase in size, the problem of electrical conductivity becomes more critical in achieving optical uniformity and functionality over the entire area of the product. For example, in the case of electrochromic windows, as the window becomes larger, there is a need for the resistivity to be lower, otherwise the uniformity of the electrochromic window considerably changes from the contact areas to the center of the window.

Systems have been developed in the past that do not appropriately solve the above problems. In one of these systems, non-electrical conductive substrates (rigid, such as glass and polycarbonate; or flexible, such as PEN, PET, etc.) are coated, at least on one of their surfaces, with a layer of transparent and highly electrically conductive material, e.g., ITO (a non-organic film), organic films such as Orgacon from Agfa, combinations thereof, ZnO films, etc. Generally, these films require a high temperature deposition process in order to achieve desired electrical conductivity and transparency levels. A drawback with these films is that they do not properly work on large area displays or electrochromic devices, having square meter surfaces. In this case, the thickness of the conductive deposition must be increased in order to insure a sufficiently good electrical conductivity; and, since these conductive layers are absorbing or reflecting the visible light, the advantage of a good electric conductivity cannot be achieved without sacrificing some of the light transmissibility, i.e., the transparency of the device.

### BRIEF DESCRIPTION OF THE DRAWINGS

FIG. 1 illustrates a film with an array of metal wires deposited or printed on an optically transmissive substrate.

FIG. 2 illustrates a metallic array deposited over a medium or low quality electrically conductive film.

FIG. 3 illustrates a graph of transmittance of a 1 cm² electrochromic elementary cell 5 seconds subsequent to application of variable driving voltages.

FIG. 4 illustrates a graph of experimental transmissibility at every elementary cell (at every succeeding centimeter from the border).

FIG. 5 illustrates a graph of effective potential as a function of the distance from cell border.

FIG. 6 illustrates an equivalent circuit of a 20 cm long electrochromic cell where the electrical parameters are Rc=55Ω, Rs=100Ω, Rp=15 KΩ, and Cp=50 μF, with an applied voltage of 3 volts.

FIG. 7 illustrates an electrical circuit representing a 1 cm wide elementary cell.

FIG. 8 illustrates a graph of effective potential at each of the 1 cm wide elementary cells of a 20 cm wide electrochromic device.

FIG. 9 illustrates a graph of a comparison of the experimental voltages dropping at every elementary cell of a 20 cm wide electrochromic device, as calculated for the equivalent circuit illustrated in FIG. 6.

FIG. 10 illustrates a graph of simulated voltages for the same electrochromic film in a one meter wide electrochromic device for three different values of the resistivity of the conductive supports with an applied voltage of 3 volts.

FIG. 11 illustrates a graph of simulated voltages for the same electrochromic film in three electrochromic devices, having different widths (10 cm, 20 cm, 100 cm), with a resistivity of the conductive supports equal to 55 ohm square and the applied voltage 3 volts.

FIG. 12 illustrates an electrochromic assembly where micron-sized strips of conductive metals are deposited on the inner conductive ITO layers.

FIG. 13 illustrates an elementary cell for electrochromic devices where the conductive supports contain metal conductive strips as illustrated in FIG. 12.

FIG. 14 illustrates a graph of the same set of data illustrated in FIG. 9 (dots) reproduced by equation (1) (continuous line).

FIGS. 15A-16D illustrate a process in accordance with embodiments of the present invention.

FIGS. 17A-17B illustrate a process and apparatus in accordance with embodiments of the present invention.

FIGS. 18-19 illustrate graphs of ITO characteristics as a function of thickness.

### DETAILED DESCRIPTION

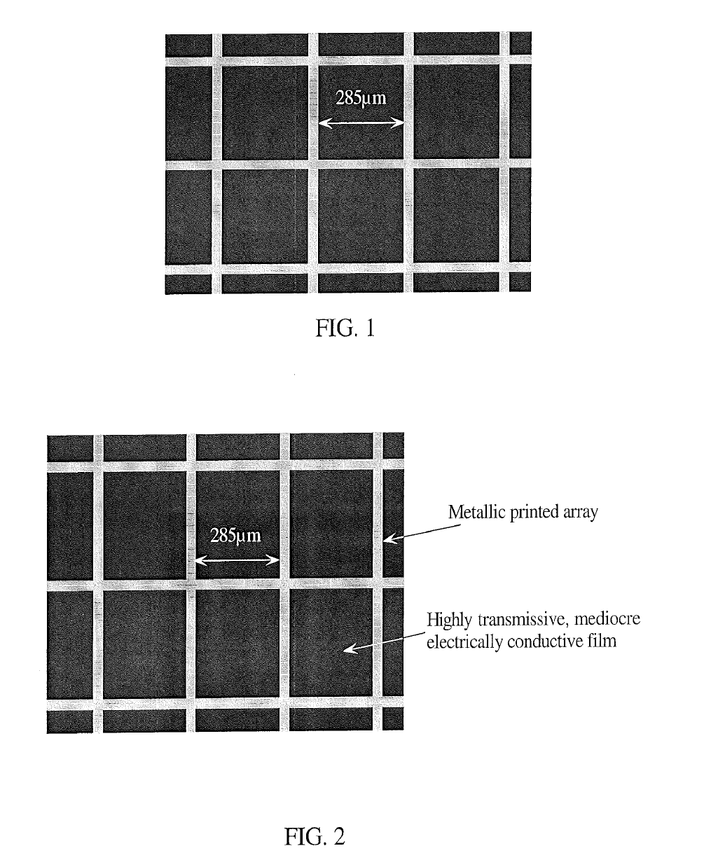

FIG. 1 illustrates a solution to the aforementioned problems that utilizes films with an array of metal wires deposited or printed on the optically transmissive substrate, utilizing very conductive metals such as Ag, Cu, etc. By doing so at variable resolutions and densities, one can achieve suitable optical transmission, on one hand, and also resistivity as low as 10⁻³ ohm/sq or lower. These conductive supports can be produced by low cost processes, for example through an inkjet process or any other process like screen printing to deposit copper ink followed by photosintering, as described in U.S. Patent Application Ser. Nos. 61/053,574 and 61/081,539, which are incorporated by reference herein.

A problem is that in many of the applications, such as display and electrochromic windows, it is necessary to apply the electric field continuously, meaning that there are not any locations on the substrate where no conductive electrode is available. Referring to FIG. 2, printing techniques such as inkjet, smart dispensing, etc. may be utilized to address this problem, where one can economically deposit such metallic arrays (e.g., Ag and Cu) over medium or even low quality electrically conductive films, with excellent optical transmission properties (ITO, SnO, CNT films, graphene films, ZnO, etc.) in such a way to achieve a very highly electrically conductive film with a suitable optical transmission. This type of film on transmissive substrates, such as glass, polycarbonates, PET, mylar, etc., has numerous applications, in particular in flexible electronics, display, solar cells, electrochromic windows, electrophoretic displays, and any type of flexible displays and smart windows.

Extraordinary transparent conductive films may be achieved by combining on a polymeric, or even glassy transparent, substrate a coating with very high transparency but with not very high electrical conductivity. At this stage, the substrate cannot be used as a proper substrate for optical devices such as flexible displays or electrochromic windows, etc., due to the fact that the resistivity is too high. In order to lower the resistivity, the thickness of the transparent layers must be increased, and as a result, the transmission of the substrate decreases. The present invention achieves an optimal combination of transparent electrically conductive film with an addition of a metallic mesh (or any equivalent pattern) to achieve almost any desired resistivity (e.g., a range of 10⁻³ Ω/sq to 300 Ω/sq).

The invention may utilize metallic meshes, or what are referred to as expanded metallic foils, similar to the Exmet product produced by Dexmet in Wallingford, Conn. For example, Dexmet has a type of metallic meshes with transparency of 85% with 364 openings per square inch, which is equivalent to openings approximately 1 mm×1 mm. Laminating these metallic meshes with transparent conductive films, even having high resistivity, achieves superb overall substrates (either flexible or rigid) for solar cells, printed electronics, flexible displays, smart windows such as electrochromic windows, etc.

Many materials may be used for the base inert high transparent supports for the both the metal meshes and continuous conductive layer, such as glass, polycarbonates, PET (polyethylene terephthalate), PEN, mylar, etc.

Typical electrochromic devices are made with a central plastic electrochromic film sandwiched between the conductive surfaces of two glass or plastic supports. When the electric properties of the different materials, involved with electric switching of the device, are not properly selected, a very peculiar phenomenon is observed. The device under the application of the required voltage does not color (become opaque) in a uniform manner across its surface, but colors deeply at the borders with respect to the center. In a worst case, the light absorbance in the center remains lower than that at the borders even after long periods of electrical feedings. This occurs because the electrical potential across the conductive support layers is not constant across the device plane but decreases going from the borders to the center. The following is an example of this phenomenon, where the materials involved are related to U.S. Published Patent Application No. WO2006/008776A1.

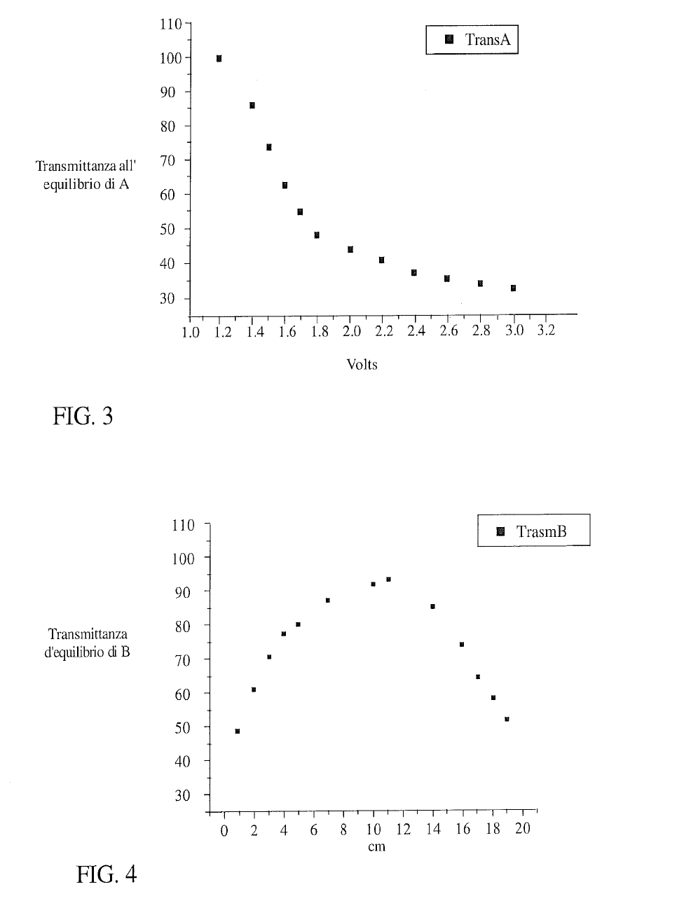

Using an electrochromic film, having a formulation of 35% Poly Vinyl Formulae (PVF), 4% Ethyl Viologen (EV), 2% Hydroquinone (HQ), 59% Propylene Carbonate (PC), a thickness of 90 microns, and an electrical DC resistivity equal to 1.7 Mohm cm, sandwiched between a glass support with inner conductive surfaces having a resistivity equal to 50 ohm square, it is observed that a device having an area of 1 cm² behaves like an ideal electrochromic cell where the optical transmissibility is constant all across the area of the cell at any time after the application of the driving voltage. This elementary cell is utilized to establish a phenomenological correspondence between the optical transmissibility, as measured at λ=600 nanometers, and the value of the applied voltage. This correspondence is shown in the graph in FIG. 3. Transmissibility has been measured after 5 seconds from the application of the driving voltages.

Then measured is the optical transmissibility of an electrochromic cell, having a 1 cm×20 cm rectangular shape. All the other parameters remain equal to those of the elementary cell above discussed. This cell can be considered as made by 20 of the previously described elementary cell. A driving voltage equal to 3 volts was applied across the major dimension of the cell and the optical transmissibility was measured at each of the elementary cell after 5 seconds from the application of the driving voltage. The results are shown in the graph in FIG. 4.

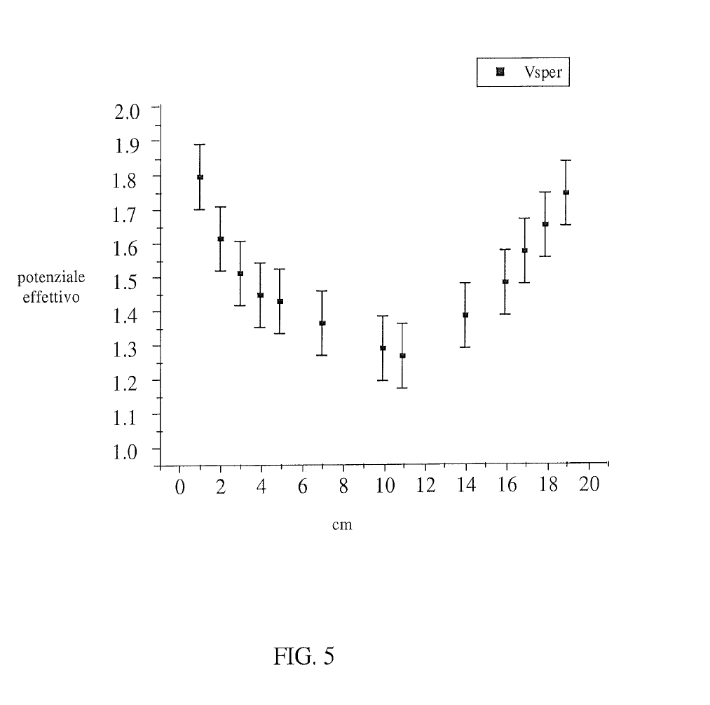

Since the values of the transmittance have been linked to the value of the voltages (see FIG. 3), the local value of the transmittance at any elementary cell can be associated to a local value of the voltage. The trend of the voltage at the different elementary cells is shown in FIG. 5.

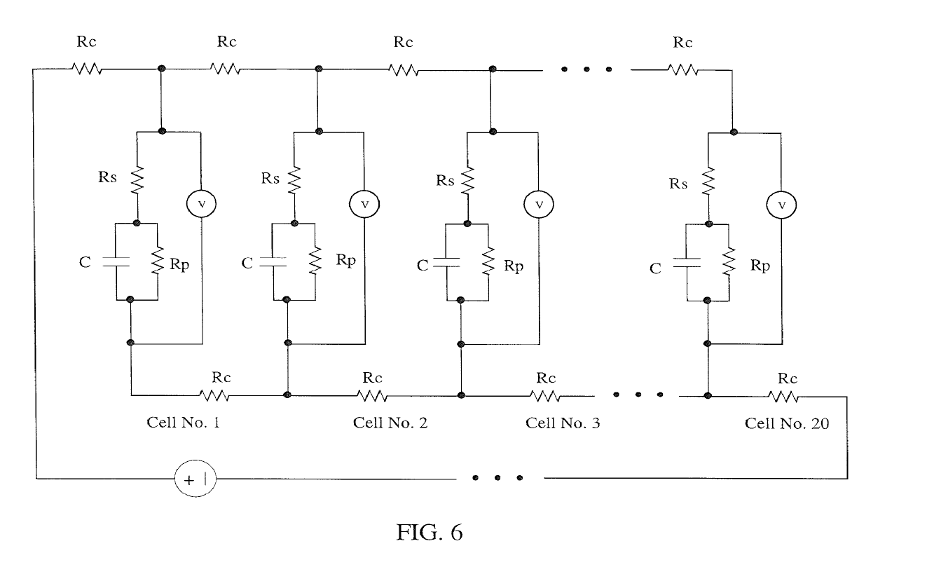

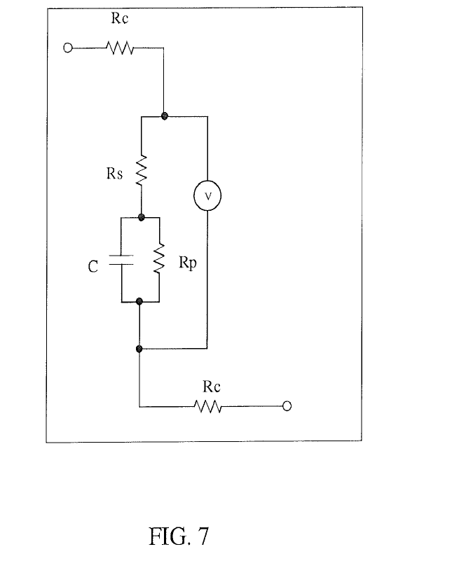

The graph in FIG. 5 shows that the voltage gradually decreases going from the border to the center of the cell. Developed is an electrical model of the electrochromic devices, by considering them as a sequence of elementary cells 1 cm wide. The model is based on the equivalent circuit illustrated in FIG. 6. Each of the elementary cells is equivalent to the circuit illustrated in FIG. 7. Rc, Rs, Rp and C are the resistance of the conductive support, the resistance of the contact between the conductive layer and the electrochromic film, the resistance of the electrochromic film, and the capacitance of the electrochromic film, respectively, for an elementary cell.

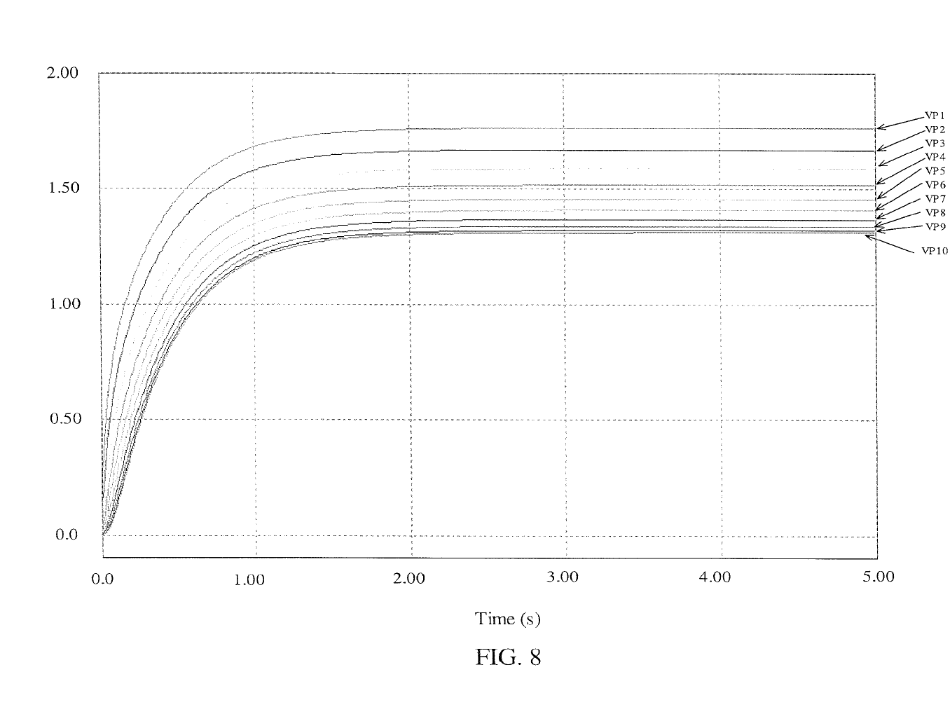

By means of the above model, it is possible to calculate the value of the potential falling at every elementary cell, starting from the border and going to the center of the device. For example, in the case of a 20 cm wide device, represented by 20 successive elementary cells, the potential falling across each of the elementary cells is shown in the graph in FIG. 8, starting from the border (cell 1) and going to the center (cell 10) of the device.

The values of the Rs, Rp, and Cp are those obtained by the fit discussed in the following. As it is possible to see when applying to the cell a border voltage of 3 volts, every elementary cell experiences a gradually decreasing voltage from the border to the center of the device. Stationary conditions (the voltages remain fixed in time) occur after a couple of seconds from the voltage applications. Thus, one can refer to the experimental data taken after 5 seconds from voltage application as stationary condition data.

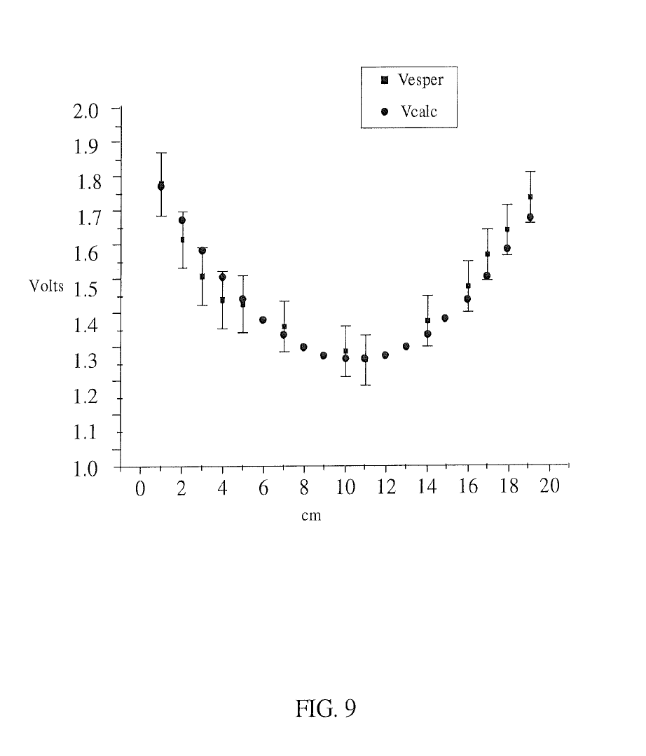

This model has been tested by comparing the experimental data reported in FIG. 5 and those calculated by using the above model, with the results shown in the graph in FIG. 9.

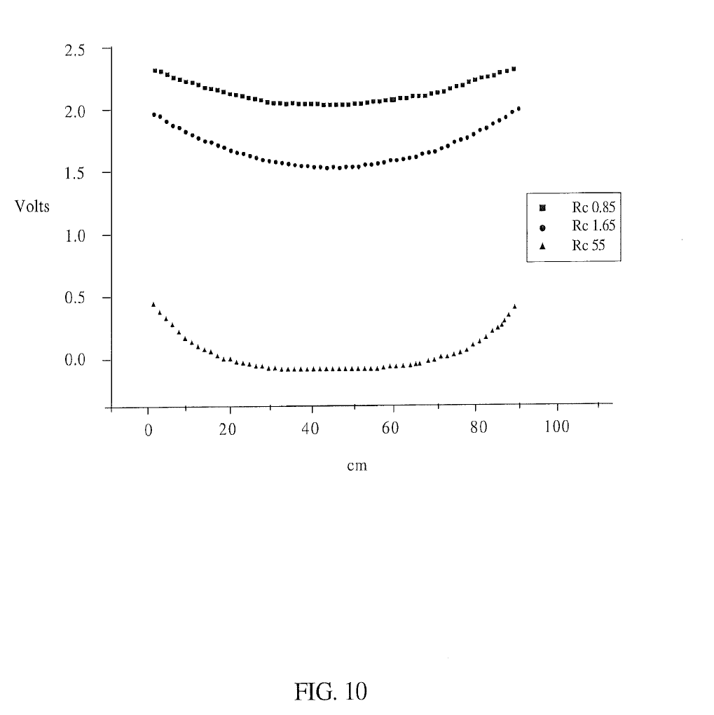

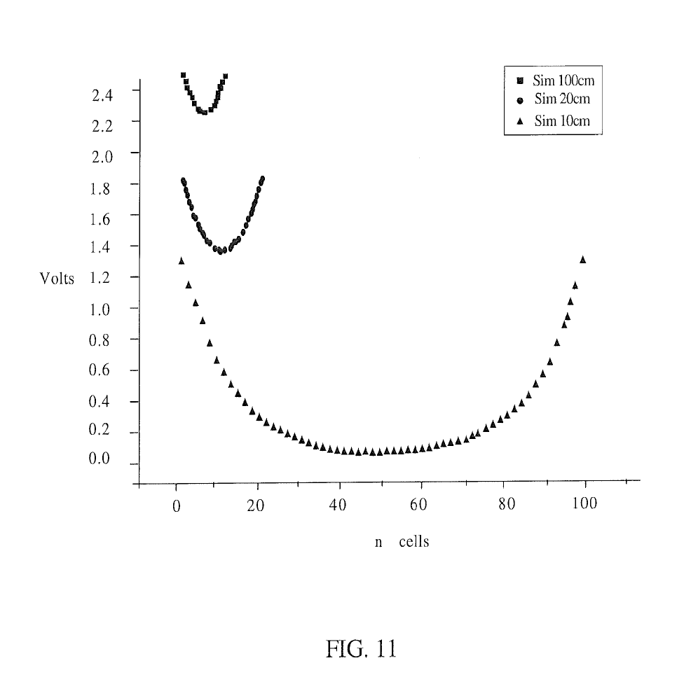

The optimized parameters were the Rs, Rp, and Cp, since Rc was known. Using this model, the voltage dropping at the elementary cell in the case of a 1 meter wide electrochromic devices is calculated, which according to the model has been divided into 100, 1 cm wide, elementary cells. The results are shown in the graph in FIG. 10.

Three curves are shown, obtained for three different values of support square resistivity. It is interesting to notice that, for a one meter wide electrochromic device, when Rc has a value of 55 ohm square (usually this is the value of RC for transparent ITO conductive glass supports) the voltage experienced by the electrochromic film across the device has two features:
a) It reduces to a very low value even next to the border (the applied voltage in the case of the simulation was 3 volts);
b) The voltage reduces almost to zero in the center of the device.

This example clearly shows that is impossible to obtain a properly working wide electrochromic device by using a conventional conductive glass support. The example represented in FIG. 10 also shows that in order to solve the problem, very low resistivity of the conductive supports is required. When Rc is reduced to 0.85 ohm square, the voltage remains very close to 2 volts all across the device, with a reduction from the border to the center on the order of 10%.

The effects discussed above depend dramatically on the device dimensions as indicated in FIG. 11, where simulations are represented for devices of three different sizes (10 cm, 20 cm, and 100 cm).

The dropping of the potential across the device cannot be balanced by increasing the applied voltage, since higher applied DC voltages would dramatically reduce the life-time of the devices. On the other hand, it is also impossible to reduce the resistivity of conductive supports: this strategy would lead to a ticker ITO coating of the supports, and a severe reduction of their optical transmissibility.

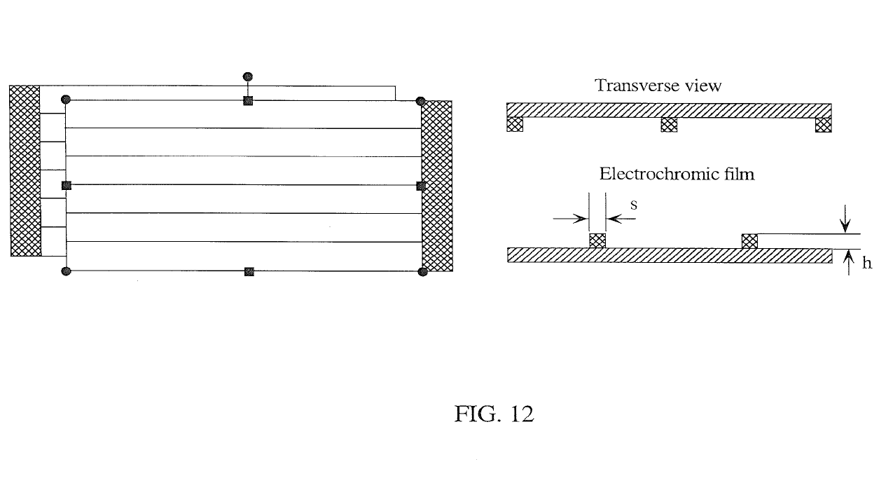

Presented is a solution to the above discussed problem by utilizing ITO conductive supports where very small metal conductive strips are deposited, as illustrated in FIG. 12.

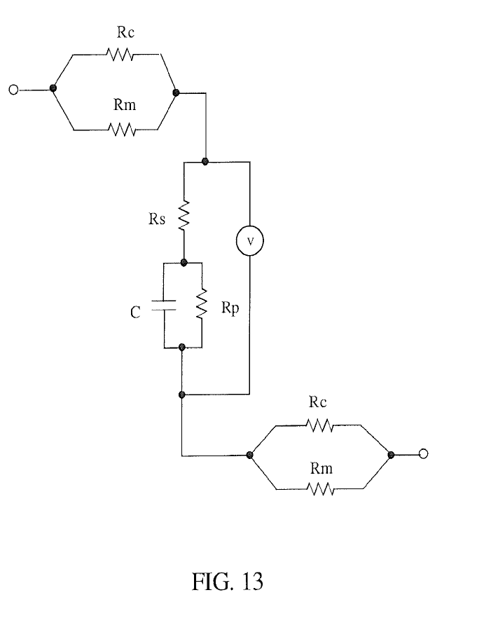

Strips of conductive material may be deposited at a distance of one cm from each other. An electrically equivalent circuit of the electrochromic device is similar to that represented in FIG. 6, but where each of the elementary cells is modified as illustrated in FIG. 13. The conductive layers are treated as two parallel resistors: one of which is the ITO surface (Rc) and the other is the metal strip (Rm).

The metal may be made by copper deposited nanoparticles. The resistivity of this material, according to Chen et. al. (J. Applied Phys., 102, 2007), is equal to 1.76×10⁻⁶ ohm cm. The geometry of the deposited strips may be s=20 microns and h=20 microns (see FIG. 12 for s and h definitions), and the value of Rm equal to 0.45 ohm. Therefore, the value of Rm is only 1% with respect to Rc. This means that for long distance conduction, Rc can be ignored. In other words, as long as a long distance condition is considered, it can be assumed that the conductivity of the support is equal to that of the conductive metal strip.

In order to establish an optimal geometry of the conductive strip, two factors are taken into account:
a) The maximum reduction of the voltage from the border of the cell to its center should be below a prefixed value, which should be that above which the human eye starts to perceive the difference in coloration (opaqueness) created by the non-uniformity of the potential across the device. A good estimate of this value is 5%.
b) The strip of conductive material should not decrease the optical transmissibility of the transparent support more than a prefixed value. This value can be assumed to be 1%.

The following description provides how these prefixed limits lead to a determination of the geometry (s and h) of the conductive strips.

The stationary voltages determined by the numerical calculations made on the basis of the equivalent circuit illustrated in FIG. 6 may be determined by the following analytic function:

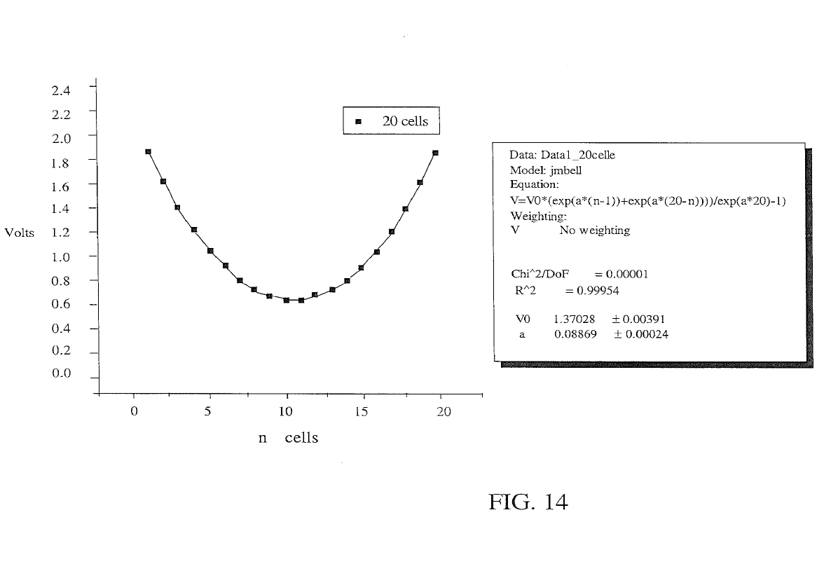

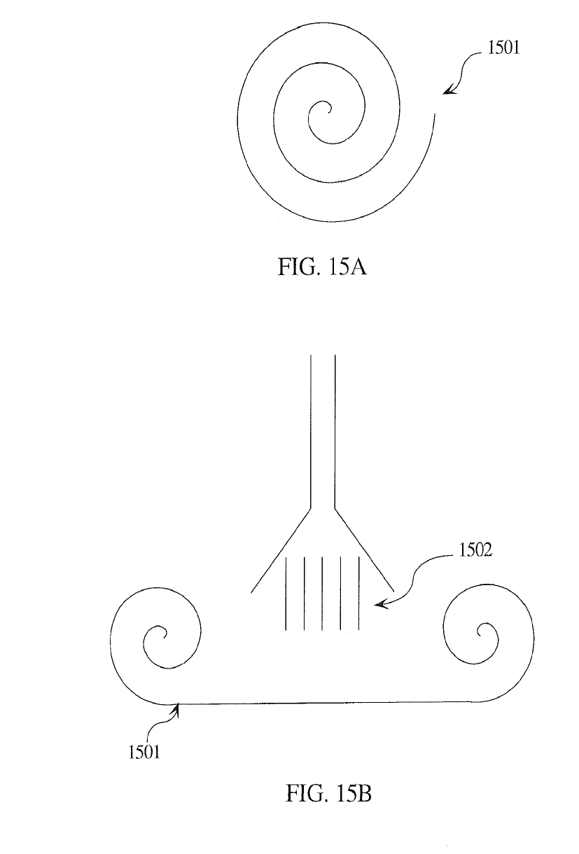

V(n)=A{exp[αx]+exp[α(L−x)]}/{exp[αL]−1} (1)

where L is the total length of the device (see FIG. 14), and A and α are parameters depending on the electrical parameters of the equivalent circuit. FIG. 14 shows the perfect equivalence of the voltages determined by numerical calculations and those obtained by equation (1) once the values of A and α are properly chosen.
A=1.37028; α=0.08869

An equation similar to equation (1) has been found to be the analytic solution for the voltage across an electrochromic cell represented by a simplified equivalent circuit where no capacitors are included (see J. M. Bell, I. L. Skryabin, G. Vogelman, Proc. Electrochem. Soc. 196-3 (1997) 396-408). In that case, the electrochromic device is made by an electrolytic solution sandwiched between electrochromic solid state layers. The cell is powered at constant current conditions. It is important to note that the equation remains valid in the case where the device is fed at constant voltage, and that the value of α to be used is very close to that calculated by the analytic expression given by Bell et al.

$$∝ = \sqrt{2 \frac{Rc}{{ρ}_{el} d}} \qquad ( 2 )$$

where Rc is the square resistance of the support, ρₑₗ and d are the resistivity and thickness of the electrolyte, respectively, in the case of the Bell device (the resistivity and thickness of the electrochromic layer in the present case). Determined is an optimal value of α equal to 0.0886, when interpolating the numerical solution of V by equation (1); and, a value of α equal to 0.0856, when using equation (2) and the values of Rc, and Rp=ρₑₗ d previously found into the numerical simulation of the V experimental values.

On the base of the above results, both equations (1) and (2) can be utilized for the following considerations.

One operative parameter for an electrochromic device according to embodiments of the present invention is the relative gap between the voltage dropping at the electrochromic film at the border V(0), and the voltage dropping in the center of the device V(L/2). This parameter can be defined according to equation (3):

$$Δ V = \frac{V ( 0 ) - V ( L / 2 )}{V ( 0 )} \qquad ( 3 )$$

An explicit relation for this parameter can be obtained by using equation (1), and considering that in a practical case, the values of α and L are such that the exponential functions can be approximated by a polynomial expansion truncated at the second order, where such an expression assumes the simple following form:

$$Δ V = \frac{{( α L )}^{2}}{2 ⌊ 4 + 2 α L + {( α L )}^{2} ⌋} \qquad ( 4 )$$

In a practical application, ΔV is below a limit value such that the corresponding lack of homogeneity in the device coloration, linked to voltage dropping, is not appreciated by human eyes. Refer to this as limit ΔVm:

$$∝ \leq \frac{\sqrt{Δ Vm ( 2 - 3 Δ Vm )} + Δ Vm}{L ( 0.5 - Δ Vm )}$$

For commodity, adopt the following definition:

l(ΔVm)=(\sqrt{ΔVm(2−3ΔVm)}+ΔVm)/(0.5−ΔVm)

Taking into consideration equation (2), and considering when depositing a tiny strip of metal at every elementary cell in such a way that Rc becomes equal to Rm (the resistivity of the metal), it is easy to show that the width (s: see FIG. 12) of the metal strip fulfills the following condition:

$$s \geq \frac{2}{l ( Δ Vm ) dh} ( \frac{{ρ}_{m}}{{ρ}_{el}} ) {L}^{2} \qquad ( 5 )$$

ρₘ=resistivity of the metal in ohm cm;

ρₑₗ=resistivity of the electrochromic film in ohm cm;

L=dimension of the device in cm;

h=the height of the metal strip as measured from the ITO layer in cm;

d=the thickness of the electrochromic layer in cm.

Only s is without dimension: it is divided by the unit length in cm.

Equation (5) determines the inferior limit of the width of the metal strip. The superior limit can be determined when considering the reduction in the optical transmissibility of the support due to the presence of the metal strip. Consider that the metal strip is completely opaque. In this, s×1 cm is the area of the elementary cell, which becomes opaque, so the value of s coincides with the relative loss of transmissibility of the support after the metal strip deposition. If δT is referred as the superior limit imposed to this loss of transmissibility of the used conductive support, then the superior limit in s is expressed as:

s≦δT (6)

In order to clarify how the limits represented by equations (5) and (6) operate, consider the following realistic example. Assume that a 2 meter long device is manufactured (L=200 cm), and the values of other parameters are:

d=100 microns

ρₑₗ=2×10⁶ Ωcm

ρ_{M}=1.76×10⁻⁶ Ωcm

h=20 microns

δT=0.01 (1%)

ΔVm=0.05 (5%), a practical value for which no inconsistent color (opaqueness) is observed.

With these realistic values, the limit equation determines:
34 microns≦s≦100 microns

At this stage, to select any of the values of s in the above interval becomes only a practical determination for the manufacturer. For example, more than one strip per unit cell could be utilized instead of a single one. In this case, the width(s) would become the total width of the n strips deposited on the base ITO layer for each unit cell. This multi-strip configuration may be utilized in the case where the resistivity of the electrochromic materials becomes lower than those above indicated. For example, electrochromic materials of the type used in the patent by Chidichimo et. al. can have resistivity down to 0.4×10⁻⁶ Ωcm. In this case, in order to maintain a ΔVm=0.05 one should have s=150 microns, e.g., 3 strips of 50 microns each. Correspondingly, the superior limit is shifted to 150 microns, but the reduction in the optical transmissibility of the support still would remain acceptable (1.5%).

A net configuration of conductive strips, instead of a series of parallel conductive lines, may be utilized, such as in a case where the driving power is supplied from different sides of each support. In this case, the limits on (s) calculated by equations (5) and (6) are divided by a factor of 2.

Embodiments of the present invention utilize conductive supports where short range electrical conduction is ensured by a uniform layer of ITO or other organic or inorganic conductive materials, and where the long range conduction is ensured by tiny strips of metal or other conductive materials of very low resistivity (typically having ρ≦10⁻⁵ Ωcm). One may select an appropriate configuration of the strips by using equations (5) and (6).

Previously described is a mathematical/physical model of an electrochromic device for the purpose of making very large electrochromic smart windows. The substrate material for these windows may be glass (both electrodes), may be transparent conductive films (both electrodes), or any other combination between a rigid transparent conductive substrate and a flexible transparent conductive film.

A problem solved was to produce a low cost, very transparent and very conductive film. In particular, there was a desire to implement very low cost substrates, e.g., incorporating soda lime glass substrates (the glass material that is used for windows in buildings) or flexible low cost very transparent and very conductive films for the aftermarket (retrofit existing windows in a building with a smart electrochromic window without replacing the existing windows).

With such constraints of temperature the substrate can sustain, manufacturing cost, transparency, electrical conductivity, etc., having a metal grid electrode on the substrates instead of one continuous transparent conductive film was investigated. Indeed, films such as disclosed in U.S. Published Patent Application No. 2005/0122034 were tested, which demonstrated that only by using these films instead of the usual ITO coated flexible substrates that are commercially available one can properly drive an electrochromic film with the width of at least 1 meter. This is very important because generally the windows are very large and how wide the electrochromic device affects the final cost and optical appearance of the smart windows.

The reliability of these electrochromic devices and lifetime were tested. Observed was that even at the high resolution of the metallic grid as it exists in the film, the electric field was not uniformly distributed in the empty space between the edges of the metallic grid, and a checkerboard pattern was observed. On the other hand, a desirable width of the metallic lines is less than approximately 20 micrometers, and even more desirably less than 10 micrometers. Furthermore, as the previously disclosed model shows, the transparency and the resistivity of the film significantly depends on the density of the metallic lines in the grid. If very low resistivity (less than 1 ohm/sq) is desired, then a very dense metallic grid is needed, but this will impact a desired transmissivity that is at least greater or equal to 70%, and especially a more desired 80%. As the inventors sought a solution, the previous model was conceived. Solutions determined that between the metallic lines of the grid another transparent conductive material was needed with a requirement that this film would be very transparent but with a relaxed electrical conductivity due to the existence of the grid. Furthermore, if the temperature of deposition of these films, either organic or inorganic, is lowered, the process is compatible with low cost transparent substrates as stated above.

Using ITO films, and/or organic films (for example from Agfa), it was discovered that as long as the metallic grid is exposed to the electrochromic material, the lifetime of the device is merely hours, because it gradually deteriorates due to an etching effect of the metallic lines by the electrochromic material. Now, in addition to transparency, conductivity, cost, temperature of manufacturing, a very difficult issue of reliability and lifetime needed to be addressed.

A solution conceived was to create a design that included a function of passivation for the metallic lines as a separation between the metallic lines and the electrochromic material with a material inert to the chemical actions of the electrochromic material. Such a design needed to address:

(1) transmission characteristics of the material;

(2) electrical conductivity characteristics of the film;

(3) step coverage characteristics this film possesses to protect the metallic grid;

(4) the chemical nature of the film that protects against the chemical effects of the electrochromic material on the metallic grid;

(5) at what temperature this material is deposited in order to be compatible with certain substrates, such as PET (e.g., less than 180 degrees C.).

The properties of the present invention to address the foregoing needs are:
large area deposition techniques at temperatures lower than 180 degrees C., more preferably in a range of temperatures between 140 and 180 degrees C.;
dielectric properties sufficient (not to be purely metallic due to the chemical reactions) to become a proper passivation layer and protective layer against the chemical attack of the electrochromic material against the metallic grid or any metallic substrate;
transparency greater than at least 70%, and more preferably greater than 80%;
electrical conductivity lower than 500 ohm/sq, and more preferably lower than 100 ohm/sq;
the film deposited with techniques that allow good step coverage.

Organic base films do not possess these qualities, and existing organic transparent films are etched by the electrochromic material. It is possible that in the future these films may achieve the characteristics stated above including the chemical stability, and their usage may be revisited.

As a result, focus was placed on the tertiary system comprised of indium, tin and oxygen (ITO). The metallic nature of indium tin without any oxygen, and other characteristics, are not suitable. The introduction of oxygen in the process was necessary. What needed to be determined was how much oxygen in order for the resulting film to have the properties summarized above.

In the tertiary system, e.g., indium tin oxide, the sheet resistance of the film for a constant oxygen flow is dependent on the substrate temperature. For example, the sheet resistance for the temperature range of interest (140 to 180 degrees C.) drops sharply as the substrate temperature is higher. On the other hand, the energy band gap that characterizes the dielectric nature (as a result the passivation nature and chemical resistance nature) also changes increasing. Furthermore, the transmittance of the ITO films changes drastically from a transmittance of less than 70% at 100 degrees C. to a transmittance of over 90% when the temperature is 170-180 degrees C.

Being bound by temperature of deposition between 140 and 180 degrees C., one can define the desired characteristics of this ITO film as having resistivities smaller or equal to 40 ohm/sq, having an energy band gap larger than 4.125 eV and a desirable transmission greater than 75%.

The transparency and electrical conductivity of ITO film strongly depend on the oxygen flow rate during the manufacturing process (see Ying Xu et al., “Deposited indium-tin-oxide (ITO) transparent conductive films by reactive low-voltage ion plating (RLVIP) technique,” Journal of Luminescence, 3 pages, Mar. 14, 2006). As the gas flow rate of oxygen increases, the sheet resistance also increases, and it is desirable in the manufacturing process to hold the gas flow rate of oxygen larger than 1 sccm, but preferably not exceeding 30 sccm.

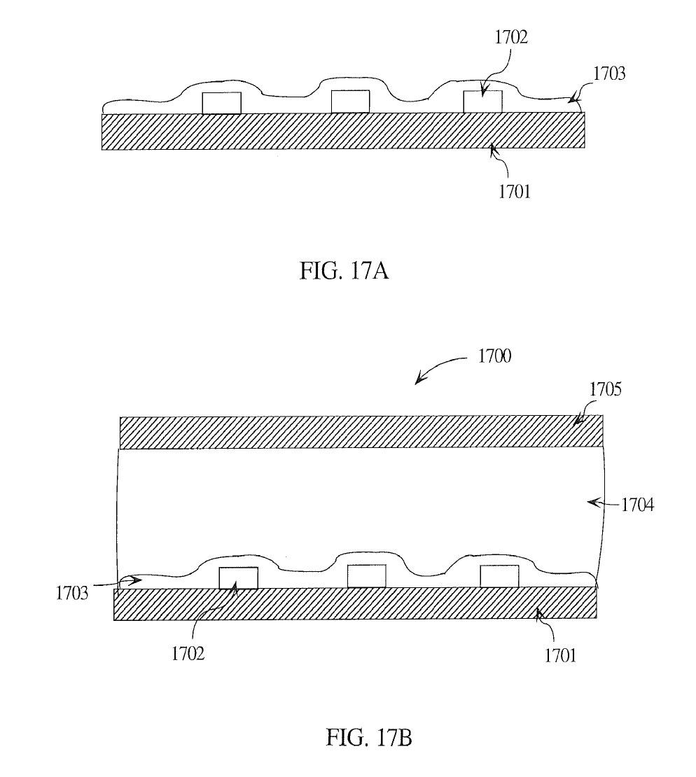

Referring to FIGS. 17A-17B, it was therefore determined for solutions to previously stated problems:
1. A low cost transparent conductive substrate for use in electrochromic devices will have a metallic grid 1702 deposited directly on a transparent substrate 1701.
2. In order for this substrate with metallic grid to be used for electrodes for electrochromic devices 1700 (electrochromic device 1700 can be substituted for the device shown in FIG. 12), it possesses a specific transparent conductive film 1703 in the empty areas between the metallic lines of the grid 1702 that has in addition to this property a passivation effect on the metallic lines of the grid 1702, and creates a chemically inert separation between the metallic grid 1702 and the electrochromic film 1704.
3. The electrical and optical properties of the metallic grid 1702 and the additional film 1703 on the top of the metallic grid 1702 as described above may vary one with respect to the other in certain ranges according to the previously presented model.

The properties of the additional transparent electrically conductive passivating film 1704 deposited over the metallic lines 1702 are:
temperature of deposition less than 180 degrees C.;
process of deposition compatible with good step coverage;
transparency of at least 70%, preferably greater than 80%;
electrical conductivity lower than 500 ohm/sq, preferably lower than 100 ohm/sq;
passivation and dielectric properties that provide an inert chemical barrier between the electrochromic material 1704 and the metallic grid 1702.

If, for example, this film 1703 is produced utilizing the tertiary system indium tin oxide, this ITO possesses the following properties:
1. temperature of deposition lower than 180 degrees C., preferably in a range of 140-180 degrees C.;
2. energy band gap greater than 4.125 eV;
3. optical transmission greater than 70%, preferably greater than 75%;
4. sheet resistance less than 100 ohm/sq, preferably less than 40 ohm/sq;
5. oxygen concentration in the film 1703 controlled in such a way that the gas flow rate of oxygen during the deposition process is greater than 1 sccm, but preferably not exceeding 30 sccm.

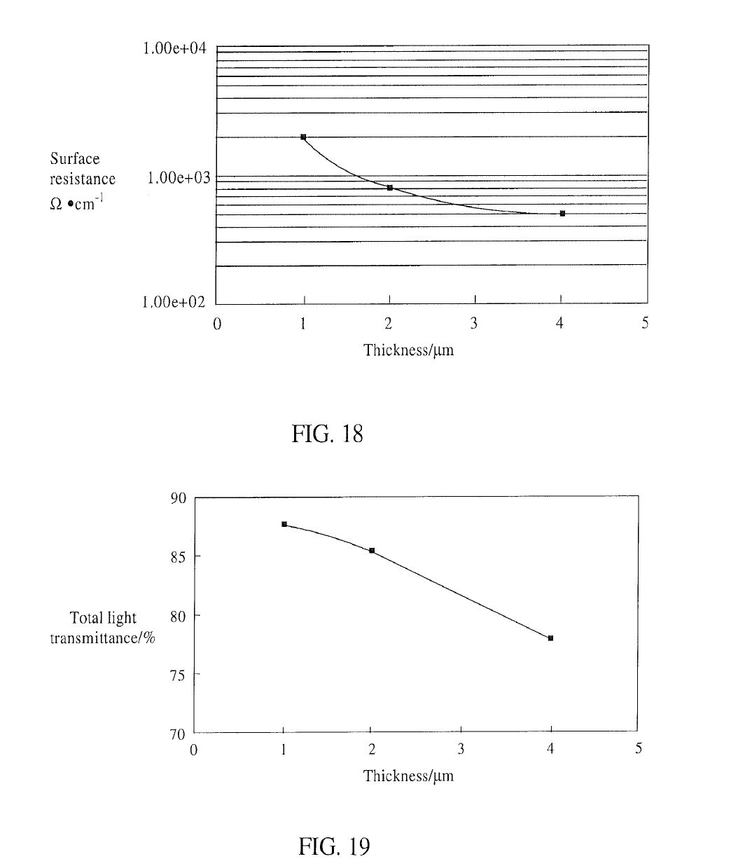

FIGS. 18 and 19 are two graphs showing the surface resistivity and the transmittance of ITO film as a function of the thickness of ITO layer 1703. Indeed, using only metallic lines as a grid one can achieve very high transmittance, but now when someone adds ITO on the top of the grid lines, one needs to consider the interplay between the resistance of the film and the transmittance. It is important that the transmittance not decrease too much with the metallic grid 1702 on one hand, but also do not want to have two resistive ITO layers in the opening spaces on the other hand. Based on these graphs, it is preferable that the ITO layer 1703 on the top is less or equal than 2 micrometer thick.

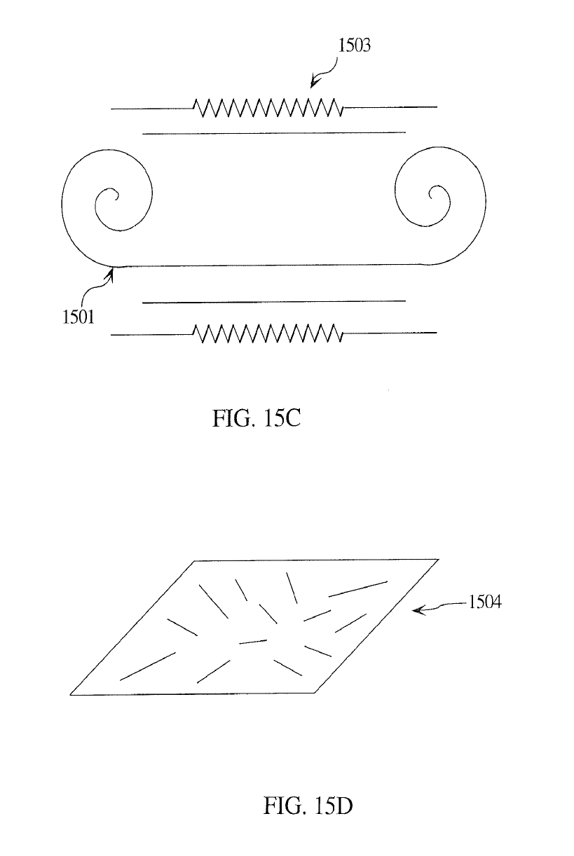

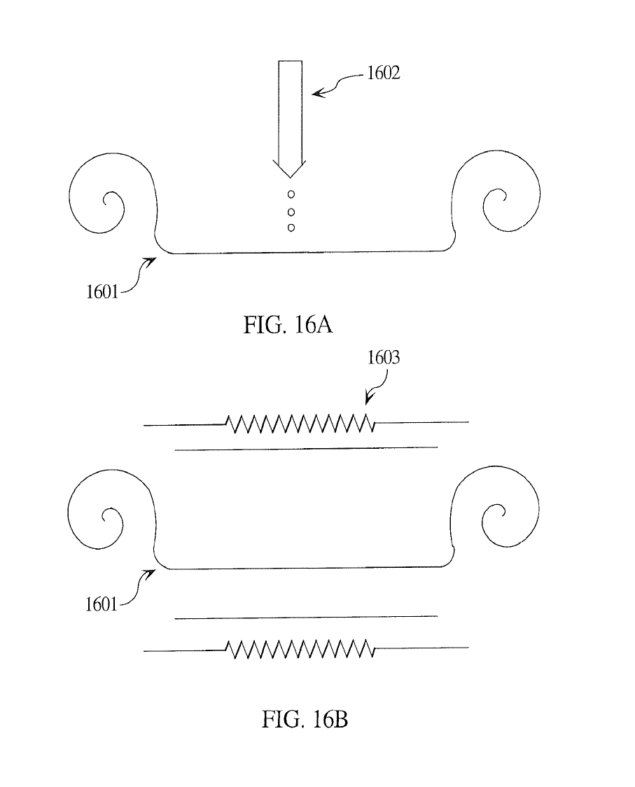

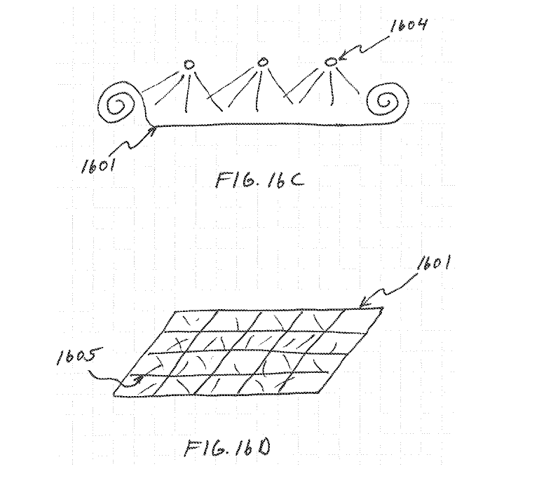

Generally, one can acquire solid or flexible transparent substrates (e.g., substrates 1701 and 1705 in FIG. 17B, and substrate 1504 in FIG. 15D, and substrate 1601 in FIG. 16D) from many sources, such as glass from Corning and NSG, etc., or flexible substrates that are not glassy, like PET (polyethylene terephthalate), mylar, etc., from many companies. There are then a number of processes to deposit an electrically conductive layer on these substrates, for example sputtering can be used for glass, or on a roll-to-roll process for flexible substrates. Graphene or CNT arrays have been used to achieve transparency and still have a conductive film. However, these films, in particular on flexible substrates, are low quality from the electrical conductivity point of view and cannot be used for large area products such as displays, solar cells, or smart windows. However, these substrates can be processed through an inkjet process for example or any other process like screen printing to deposit copper ink (the present invention may make use of metallic inks of all kinds, plus other printing techniques such as flexography, gravure, offset lithography, etc.), for example, that then will go through photosintering as described in U.S. Patent Application Ser. Nos. 61/053,574 and 61/081,539, which are hereby incorporated by reference herein. Example production steps in the case of copper ink are:
acquire a substrate 1501 (e.g., a roll of PET) (see FIG. 15A)
deposit on the substrate 1501 by a spraying process (see FIG. 15B) a suitable density of CNTs 1502, with a solvent that can be evaporated, such as in an oven 1503 (see FIG. 15C)
this achieves a low density network 1504 of CNTs 1502 on the substrate 1501 with mediocre electrical conductivity, e.g., in a range of hundreds or even thousands ohm/sq (see FIG. 15D)
the substrate 1504 with the CNT transparent coating on it is brought to an inkjet printing unit 1602 that then inkjets, for example, lines of copper ink approximately greater or equal to 10 micrometer width in a pattern (see FIG. 16A)
after the ink deposition, the substrate 1504 goes through a low temperature drying process (lower than 100 degrees C., such as in an oven 1603) in order to dry the copper ink (see FIG. 16B)
a roll-to-roll sintering process 1604 is utilized to transform the copper ink into copper lines 1605 (see FIG. 16D); such a process may be photosintering, thermal sintering, or chemical sintering.

Furthermore, a transparent adhesive may be applied to one of the substrates so that the completed film can be adhered to another substrate, such as a glass window.

Alternatively, the order of the processes in FIGS. 15A-15D can be switched with the processes in FIGS. 16A-16D so that the CNT transparent coating is deposited after the production of the copper lines in order to cover the copper lines so that the CNT transparent coating additionally functions as a passivation layer (physical barrier) between the copper lines and the electrochromic layer, such as previously disclosed with respect to FIGS. 17A-17B.

What is claimed is:

1. An apparatus comprising:
a first transparent substrate;
a pattern of conductive lines positioned on the first transparent substrate;
a transparent conductive film positioned over the pattern of conductive lines and first transparent substrate; and
an electrochromic layer positioned on the transparent conductive film, wherein the transparent conductive layer is a physical barrier separating the electrochromic layer from the pattern of conductive lines.

2. The apparatus as recited in claim 1, further comprising a second transparent substrate positioned on the electrochromic layer so that the electrochromic layer, transparent conductive film and pattern of conductive lines are sandwiched between the first and second transparent substrates, wherein the second transparent substrate further comprises a pattern of conductive lines positioned on the second transparent substrate and a transparent conductive film positioned over the pattern of conductive lines and second transparent substrate.

3. The apparatus as recited in claim 2, wherein the first and second transparent substrates are flexible.

4. The apparatus as recited in claim 3, further comprising an adhesive layer on an external side of the second transparent substrate.

5. The apparatus as recited in claim 1, wherein the apparatus has less than a 1 ohm/sq resistance to electrical energy utilized to activate the electrochromic layer.

6. The apparatus as recited in claim 1, wherein the transparent conductive layer is chemically inert to the electrochromic layer.

7. The apparatus as recited in claim 1, wherein the first transparent substrate comprises PET.

8. The apparatus as recited in claim 1, wherein the transparent conductive film has an optical transmission greater than 70%.

9. The apparatus as recited in claim 1, wherein the transparent conductive film has an optical transmission greater than 80%.

10. The apparatus as recited in claim 1, wherein the transparent conductive film has a sheet resistance less than 500 ohm/sq.

11. The apparatus as recited in claim 1, wherein the transparent conductive film has a sheet resistance less than 100 ohm/sq.

12. The apparatus as recited in claim 1, wherein the transparent conductive film has an optical transmission greater than 70% and a sheet resistance less than 100 ohm/sq.

13. The apparatus as recited in claim 8, wherein the transparent conductive film comprises ITO.

14. The apparatus as recited in claim 13, wherein the ITO film has an average thickness less than 2 micrometers.

15. The apparatus as recited in claim 13, wherein the ITO film has an energy band gap greater than 4.125 eV.

16. The apparatus as recited in claim 13, wherein the ITO film has a sheet resistance less than 100 ohm/sq.

17. The apparatus as recited in claim 13, wherein the ITO film has a sheet resistance less than 40 ohm/sq and an energy band gap greater than 4.125 eV.

18. A method for manufacturing an electrochromic window comprising:
positioning a pattern of conductive lines over a first transparent substrate;
positioning a transparent conductive film over the pattern of conductive lines and first transparent substrate; and
positioning an electrochromic layer over the transparent conductive film, wherein the transparent conductive layer is a physical barrier separating the electrochromic layer from the pattern of conductive lines.

19. The method as recited in claim 18, further comprising positioning a second transparent substrate over the electrochromic layer so that the electrochromic layer, transparent conductive film and pattern of conductive lines are sandwiched between the first and second transparent substrates.

20. The method as recited in claim 19, further comprising:
positioning a second pattern of conductive lines over the second transparent substrate; and
positioning a second transparent conductive film over the second pattern of conductive lines and second transparent substrate, wherein the second transparent conductive layer is a physical barrier separating the electrochromic layer from the second pattern of conductive lines.

21. The method as recited in claim 20, wherein the first transparent substrate is flexible.

22. The method as recited in claim 20, wherein the transparent conductive film comprises ITO deposited over the pattern of conductive lines and the first transparent substrate at a temperature less than 180 degrees C.

23. The method as recited in claim 22, wherein the ITO film has an energy band gap greater than 4.125 eV, an optical transmission greater than 75%, and a sheet resistance less than 100 ohm/sq.

24. The method as recited in claim 23, wherein the ITO film has a sheet resistance less than 40 ohm/sq.

25. The method as recited in claim 18, wherein the transparent conductive film has an optical transmission greater than 80% and a sheet resistance less than 500 ohm/sq.

26. The method as recited in claim 25, wherein the transparent conductive film has a sheet resistance less than 100 ohm/sq.

27. The method as recited in claim 18, wherein the transparent conductive film comprises ITO deposited with a gas flow rate of oxygen greater than 1 sccm, but less than 30 sccm.

28. The method as recited in claim 18, wherein the pattern of conductive lines is deposited on the first transparent substrate using inkjetting, flexography, or offset lithography.

29. The method as recited in claim 28, wherein the pattern of conductive lines is deposited as a metallic ink, wherein the method further comprises sintering the metallic ink.

30. The method as recited in claim 29, wherein the sintering is thermal.

31. The method as recited in claim 29, wherein the sintering is photo.

32. The method as recited in claim 29, wherein the sintering is performed at less than 180 degrees C.

33. The method as recited in claim 18, wherein the transparent conductive film is deposited over the pattern of conductive lines and the first transparent substrate with good step coverage.
